(19) United States
(12) Patent Application Publication
(10) Pub. No.: US 2011/0123930 A1
(43) Pub. Date: May 26, 2011

(54) Ceramic substrate preparation process

(75) Inventor: Wen-Hsin Lin, Taipei City (TW)

(73) Assignee: HOLY STONE ENTERPRISE CO., LTD., Taipei City (TW)

(21) Appl. No.: 12/805,056

(22) Filed: Jul. 9, 2010

(30) Foreign Application Priority Data
Nov. 20, 2009 (TW) 098139523

(51) Int. Cl. G03F 7/20; C23C 14/34

(52) U.S. Cl. 430/311; 204/192.15

(57) ABSTRACT

An etching-free ceramic substrate preparation process includes the step of bonding a dry film to one side of a ceramic plate, the step of applying an exposing and developing process to the dry film to form a predetermined circuit layout on the dry film, the step of coating a thin-thickness first metal layer on the ceramic plate and the dry film, the step of forming a copper layer on the first metal layer by a coating technique, the step of cutting/grinding the dry film, the first metal layer and the copper layer to remove the dry film from the ceramic plate, the step of obtaining the desired height of the copper layer on the ceramic plate, and the step of forming a second metal layer on the surface of the copper layer by a coating technique.

This application claims the priority benefit of Taiwan patent application number 098139523, filed on Nov. 20, 2009.

### BACKGROUND OF THE INVENTION

1. Field of the Invention

The present invention relates to the fabrication of ceramic substrates and more particularly, to a ceramic substrate preparation process, which utilizes cutting/grinding techniques instead of etching process to avoid damage to operators or the environment and, which is practical for making a ceramic substrate having a non gradient circuit and an equal size of the top and bottom sides of the circuit for high-precision application.

2. Description of the Related Art

Following fast development of technology and subject to the factor that people are seeking for high quality of life, the requirements for the application characteristics of products are critical. In consequence, the use of newly developed materials becomes a requisite for the fabrication of certain products. In order to achieve better transmission efficiency and smaller product size, IC package manufacturers have been investing a log of money to improve their manufacturing processes for the fabrication of electronic component parts (for, for example, mobile telephone or mini notebook computer). Nowadays, ceramic substrates have been intensively used to substitute for conventional substrates for the advantages of excellent electrical insulating properties, high chemical stability, better electromagnetic properties, high hardness, high thermal conductivity, high wearproof characteristics and high temperature resistance.

Further, during the fabrication of a ceramic substrate according to the prior art, it is necessary to bond metal and conductive layers to a ceramic plate by thermal bonding, to bond a dry film to the conductive layer, to apply an exposing and developing process to the dry film to form a predetermined circuit pattern on the dry film, and to apply an etching technique to remove the dry film, so that the desired metal layer and conductive layer in the form of the predetermined circuit pattern can be left on the substrate plate. During the etching step, an etching solution (that contains a chemical solution such as ferric chloride solution or copper chloride solution) must be used. This etching solution is harmful to human body. Improper disposal of the waste etching solution will pollute the environment.

Therefore, it is desirable to provide a ceramic substrate preparation process that does not cause any damage to the operators or the environment.

### SUMMARY OF THE INVENTION

The present invention has been accomplished under the circumstances in view. It is one object of the present invention to provide a ceramic substrate preparation process, which eliminates etching chemical etching, avoiding damage to the operators or the environment.

To achieve this and other objects of the present invention, a ceramic substrate preparation process includes the steps of: bonding a dry film to one side of a ceramic plate, applying an exposing and developing process to the dry film to form a predetermined circuit layout on the dry film, coating a thin-thickness first metal layer on the ceramic plate and the dry film, the step of forming a copper layer on the first metal layer by a coating technique, cutting/grinding the dry film, the first metal layer and the copper layer to remove the dry film from the ceramic plate, obtaining the desired height of the copper layer on the ceramic plate, and forming a second metal layer on the surface of the copper layer by a coating technique. Because the present invention does not require any chemical etching procedure, performing the ceramic substrate preparation process does not cause any damage to the operators or produce any waste etching solution to pollute the environment.

Further, the ceramic plate is obtained from a soft blank through a sintering process and then processed to form at least one hole thereon before bonding of the dry film. Further, the soft blank can be obtained from aluminum nitride or aluminum oxide.

### BRIEF DESCRIPTION OF THE DRAWINGS

FIG. 1 is a ceramic substrate preparation process flow chart in accordance with the present invention.

FIG. 2 illustrates the steps of the fabrication of ceramic substrates in accordance with the present invention.

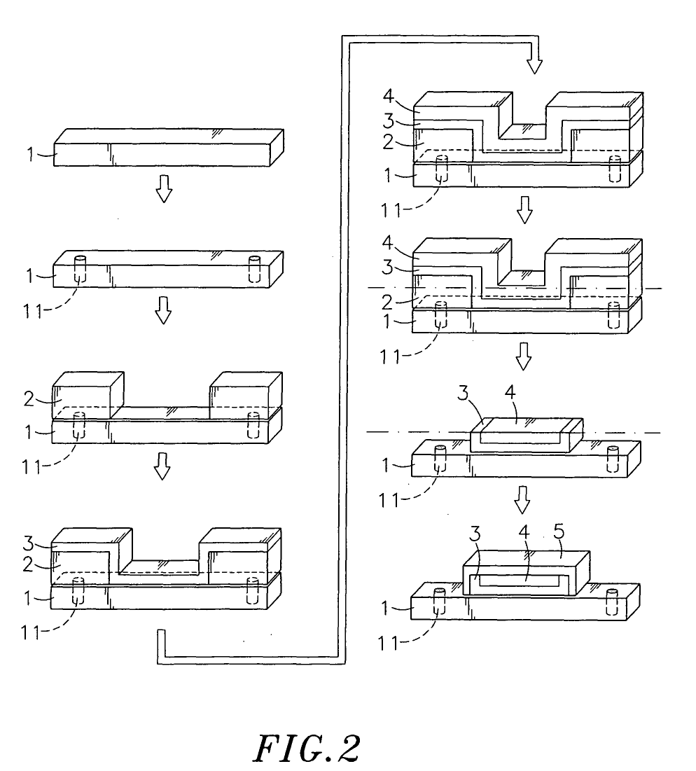

FIG. 3 a sectional side view showing a copper layer formed on the first metal layer on the dry film at the ceramic plate according to the present invention.

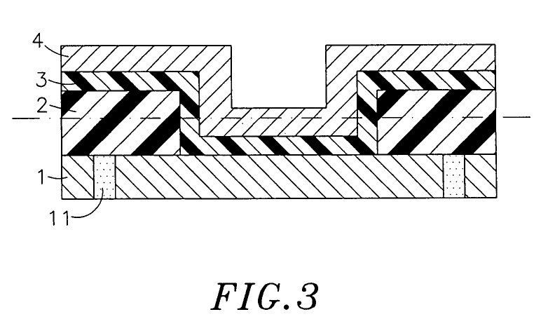

FIG. 4 a sectional side view of a finished ceramic substrate made according to the present invention

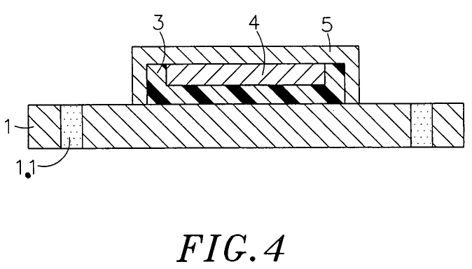

### DETAILED DESCRIPTION OF THE PREFERRED EMBODIMENT

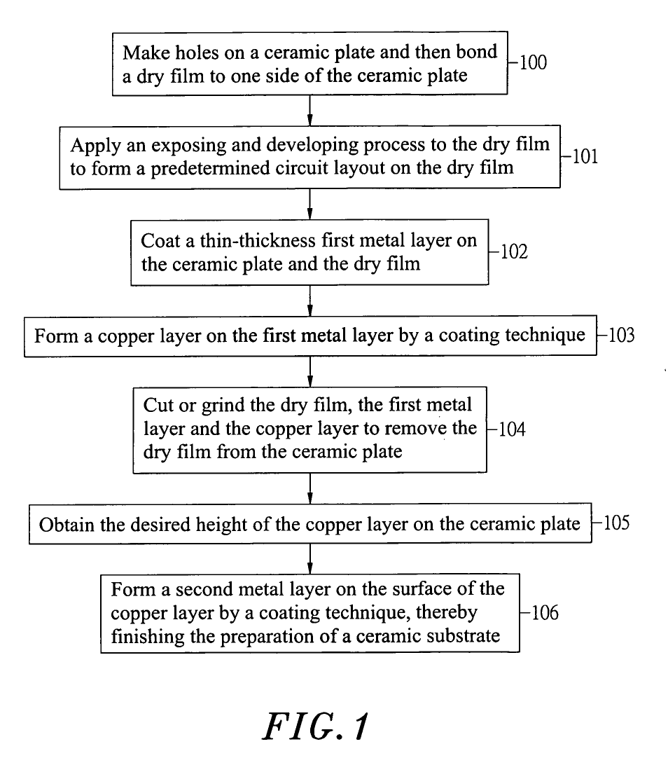

Referring to FIGS. 1˜4, a ceramic substrate preparation process of the present invention is shown comprising the steps of:
(100) Make holes 11 on a ceramic plate 1, and then bond a dry film 2 to one side of the ceramic plate 1;
(101) Apply an exposing and developing process to the dry film 2 to form a predetermined circuit pattern on the dry film 2;
(102) Coat a thin-thickness first metal layer 3 on the ceramic plate 1 and the dry film 2;
(103) Form a copper layer 4 on the first metal layer 3 by a coating technique, for example, electroplating;
(104) Cut or grind the dry film 2, the first metal layer 3 and the copper layer 4 to remove the dry film 2 from the ceramic plate 1;
(105) Obtain the desired height of the copper layer 4 on the ceramic plate 1; and
(106) Form a second metal layer 5 on the surface of the copper layer 4 by a coating technique, for example, electroplating, thereby finishing the preparation of a ceramic substrate.

The ceramic plate 1 is obtained from a soft blank, for example, aluminum nitride or aluminum oxide, through a sintering process, and then processed to form at least one hole 11. Thereafter, a dry film 2 is bonded to one side of the ceramic plate 1, and then photolithography is employed to let the dry film 2 receive a exposing and developing process, so that a predetermined circuit layout can be formed on the dry film 2. Thereafter, a coating technique is employed to coat a first metal layer 3 on the surface of the ceramic plate 1 and the dry film 2. The first metal layer 3 can be prepared from Ni/Cr/Si, Ni/Cr/Si alloy, Ni/Cr/Si+Cu alloy, Fe/Co alloy, or Fe/Co/Ni alloy. Further, the first metal layer 3 has a thickness 0.15 μm˜0.5 μm. Thereafter, a copper layer 4 is lapped on the first metal layer 3 by a coating technique that can be electroplating, vapor deposition or sputter deposition. The thickness of the copper layer 4 can be 50 μm˜75 μm. After formation of the copper layer 4, a second metal layer 5 on the surface of the copper layer 4 by a coating technique, for example, electroplating, vapor deposition or sputter deposition. The second metal layer 5 can be prepared from nickel (Ni), gold (Au) or silver (Ag), avoiding oxidation or corrosion damage to other coating materials and assuring integrity of every coating layer on the ceramic plate 1. A ceramic substrate thus made is practical for use in making high power LED, fuel battery, solar panel or solar battery.

The coating of the aforesaid first metal layer 3 can be done by depositing titanium on the surface of the ceramic plate 1 and the dry film 2 by sputter deposition, or by applying a nano-sized surfactant to modify the surface of the ceramic plate 1 and the dry film 2 and then coating a layer of nickel, chrome, gold or silver on the modified surface of the ceramic plate 1 and the dry film 2. Because the coating of the aforesaid first metal layer 3 is of the known art and not within the scope of the technical features of the present invention, no further detailed description in this regard is necessary.

The ceramic substrate preparation process of the present invention does not require a chemical etching procedure. Therefore, performing the ceramic substrate preparation process does not cause any damage to the operators or produce any waste etching solution to pollute the environment, i.e., the ceramic substrate preparation process of the present invention is an environmentally friendly process that accelerates ceramic substrate fabrication and prevents accidents during ceramic substrate fabrication.

The above described embodiment is simply an example of the present invention but not intended as a limitation. The ceramic substrate preparation process is to make holes 11 on a ceramic plate 1, and then to bond a dry film 2 to one side or each of the two opposite sides of the ceramic plate 1, and then to employ photolithography, and then to coat a first metal layer 3 on the surface of the ceramic plate 1 and the dry film 2, and then to lap a copper layer 4 on the first metal layer 3, and then to cut or grind the dry film 2, the first metal layer 3 and the copper layer 4 so as to remove the dry film 2 from the ceramic plate 1 and obtain the desired height of the copper layer 4 on the ceramic plate 1, and then to coat a second metal layer 5 on the surface of the copper layer 4. Because the present invention does not require any chemical etching procedure, performing the ceramic substrate preparation process does not cause any damage to the operators or produce any waste etching solution to pollute the environment.

In conclusion, the invention has the following advantages and features:

1. The ceramic substrate preparation process does not require any chemical etching procedure, avoiding damage to the operators or the environment. Further, the ceramic substrate preparation process is practical for making a ceramic substrate having a non gradient circuit and an equal size of the top and bottom sides of the circuit for high-precision application.

2. After formation of the copper layer 4 on the first metal layer 3, a cutting or grinding process is employed to remove the dry film 2 from the ceramic plate 1 and to obtain the desired height of the copper layer 4 on the ceramic plate 1, thereafter, a second metal layer 5 can be formed on the surface of the copper layer 4 without causing oxidation or corrosion damage to any other materials

As stated above, the ceramic substrate preparation process is to bond a dry film to one side or each of the two opposite sides of a ceramic plate, and then to form a first metal layer and a copper layer properly by means of electroplating, vapor deposition or sputter deposition, and then to cut or grind the dry film, the first metal layer and the copper layer so as to remove the dry film and to obtain the desired height of the copper layer, and then to coat a second metal layer on the copper layer. Because any chemical etching procedure is not used, the invention facilitates ceramic substrate fabrication and avoids damage to the operators or the environment.

Although a particular embodiment of the invention has been described in detail for purposes of illustration, various modifications and enhancements may be made without departing from the spirit and scope of the invention. Accordingly, the invention is not to be limited except as by the appended claims.

What the invention claimed is:

1. A ceramic substrate preparation process, comprising the steps of:
a) bonding a dry film to one side of a ceramic plate;
b) applying an exposing and developing process to said dry film to form a predetermined circuit layout on said dry film;
c) coating a thin-thickness first metal layer on said ceramic plate and said dry film;
d) forming a copper layer on said first metal layer by a coating technique;
e) cutting/grinding said dry film, said first metal layer and said copper layer to remove said dry film from said ceramic plate;
f) obtaining the desired height of said copper layer on said ceramic plate; and
g) forming a second metal layer on the surface of said copper layer by a coating technique.

2. The ceramic substrate preparation process as claimed in claim 1, wherein said ceramic plate is obtained from a soft blank through a sintering process and then processed to form at least one hole thereon before bonding of said dry film.

3. The ceramic substrate preparation process as claimed in claim 2, wherein said soft blank is selected from a group consisting of aluminum nitride and aluminum oxide.

4. The ceramic substrate preparation process as claimed in claim 1, wherein said first metal layer is selected from a material group consisting of Ni/Cr/Si, Ni/Cr/Si alloy, Ni/Cr/Si+Cu alloy, Fe/Co alloy and Fe/Co/Ni alloy, having a thickness 0.15 μm˜0.5 μm.

5. The ceramic substrate preparation process as claimed in claim 1, wherein said copper layer is lapped on said first metal layer by one of the coating techniques of electroplating, vapor deposition and sputter deposition, having a thickness 50 μm˜75 μm.

6. The ceramic substrate preparation process as claimed in claim 1, wherein said second metal layer is coated on the surface of said copper layer by one of the coating techniques of electroplating, vapor deposition and sputter deposition and prepared from a material group consisting of nickel (Ni), gold (Au) and silver (Ag).
